(19) United States
(12) Patent Application Publication
(10) Pub. No.: US 2008/0173366 A1
(43) Pub. Date: Jul. 24, 2008

(54) Gas box module of semiconductor device manufacturing equipment

(76) Inventor: Tae-Kyung Kwon, Hwaseong-si (KR)

Correspondence Address: LEE & MORSE, P.C., 3141 FAIRVIEW PARK DRIVE, SUITE 500, FALLS CHURCH, VA, 22042, US

(21) Appl. No.: 12/000,872

(22) Filed: Dec. 18, 2007

(30) Foreign Application Priority Data
Dec. 20, 2006 (KR) 10-2006-0130574

(51) Int. Cl. C23C 16/52

(52) U.S. Cl. 137/884

(57) ABSTRACT

Example embodiments relate to a gas box module for supplying a process gas into a semiconductor device manufacturing equipment. The gas box module may include a component adapted to supply the process gas into a process chamber and a block part. The component may have a first mating portion, and the block part may have a second mating portion adapted to correspond to the first mating portion, so as to align and secure the component to the block part.

### BACKGROUND OF THE INVENTION

1. Field of the Invention

Example embodiments relate to a semiconductor device manufacturing equipment. More particularly, example embodiments relate to a gas box module for a semiconductor device manufacturing equipment capable of supplying a process gas into a process chamber.

2. Description of the Related Art

Recently, due to increasing development of information communication fields and popularization of information media, e.g., a computer, semiconductor devices have been expanding to include high speed and large storage capacity. Further, with high speed integration and large capacity, integration density of semiconductor devices (constituting a memory cell) may be achieved so as to reduce a size of each unit. As a result, high integration technology for forming a multi-layer structure has also been dramatically developed.

Accordingly, in order to meet the high integration technology, unit processes for manufacturing the semiconductor device should have optimal accuracy and precision. Conventionally, unit processes of manufacturing the semiconductor device may be manufactured through various processes, such as: (a) an impurity ion implantation and diffusion process of implanting impurity ions (i.e., 3B family or 5B family) into a semiconductor substrate; (b) a thin film deposition process of forming a material layer on the semiconductor substrate; (c) an etching process, such as, photolithography of patterning the material layer passed through the thin film deposition process in a desired shape; (d) a chemical mechanical polishing (CMP) process of depositing an interlayer insulating layer on a wafer surface, and then, polishing the wafer surface entirely to remove a step; and (e) a wafer cleaning process to remove impurities. Therefore, the various unit processes may be selectively and repeatedly performed to deposit a plurality of circuit patterns on the wafer surface, so as to manufacture the semiconductor device.

Further, various process gases may be used in the unit processes for manufacturing the semiconductor device. For example, a chemical vapor deposition (CVD) process (during the thin film deposition process) may be a process of injecting at least one process gas with a predetermined vacuum pressure into a sealed process chamber, and then uniformly mixing the process gas through plasma reaction, thereby depositing a thin film on a semiconductor substrate. The process gas may be supplied into the CVD equipment in a vapor state with a temperature higher than an ambient temperature, so as to generate chemical reaction on the semiconductor substrate. In addition, the process gas supplied into the CVD equipment may uniformly move from a center to a periphery of the semiconductor substrate through a shower head disposed on the semiconductor substrate, so as to deposit a uniform thickness of thin film on the semiconductor substrate. Further, the semiconductor substrate may be heated by a heater to provide a temperature that may be equal to or similar to the process gas. Furthermore, the process gas may move along a surface of the semiconductor substrate to form a thin film on the semiconductor substrate, and may simultaneously generate by-products, e.g., a volatile gas. The by-products may be discharged with the process gas, which may not react on the semiconductor substrate, to the exterior of the process chamber via an exhaust apparatus, e.g., a vacuum pump.

Further, the process gas may be supplied into the process chamber through a gas supply apparatus, e.g., a gas box. The gas box may employ various components, e.g., a gas line, a regulator, a manual valve, an air valve, a mass flow controller (MFC), etc.

FIG. 1 illustrates a plan view of a block type gas box module of a conventional semiconductor device manufacturing equipment, and FIG. 2 illustrates a partial plan view of the gas box module shown in FIG. 1.

Referring to FIGS. 1 and 2, the gas box module may include various components, such as, a gas line, a regulator, a manual valve, an air valve, an MFC, etc. The various components may be connected to block parts using connectors (e.g., VCR), respectively. However, in order to perform high performance for the semiconductor device manufacturing equipment and to reduce the size of the gas box, the components (e.g., the gas line, the regulator, the manual valve, etc.), may be mounted on the block parts using a fastener, e.g., a screw.

Further, when the gas box modules are connected in a block shape to be mounted on the block part, gaps between the components may be restrictive in repairing and/or maintaining the components, e.g., time consuming to attach and detach the components for repairs and maintenance. Further, the gas box modules may move, e.g., shift alignment of the components during the attachment and detachment of the components. Accordingly, the fastener (e.g., screw) connecting the gas line may deteriorate, and as a result, a gasket may be damaged, which may cause gas leakage. Further, an operator of the semiconductor device manufacturing equipment may generally only visibly check for alignment of the components, which may be difficult and not accurately accessed.

### SUMMARY OF THE INVENTION

Example embodiments are therefore directed to a gas box module of a semiconductor device manufacturing equipment, which substantially overcome one or more of the problems due to the limitations and disadvantages of the related art.

It is therefore a feature of example embodiments to provide a gas box module of a semiconductor device manufacturing equipment capable of preventing and/or reducing misalignment of components constituting the gas box module during maintenance of the gas box module.

It is therefore another feature of example embodiments to provide a gas box module of a semiconductor device manufacturing equipment capable of preventing and/or reducing shifting of components constituting the gas box module.

It is therefore yet another feature of example embodiments to provide a gas box module of a semiconductor device manufacturing equipment capable of preventing and/or reducing damage to a gasket.

It is therefore yet another feature of example embodiments to provide a gas box module of a semiconductor device manufacturing equipment capable of preventing and/or reducing gas leakage.

It is therefore yet another feature of example embodiments to provide a gas box module of a semiconductor device manufacturing equipment capable of reducing maintenance and repair time of the gas box module.

At least one of the above and other features of example embodiments may be to provide to a gas box module for supplying a process gas into a semiconductor device manufacturing equipment. The gas box module may include a component adapted to supply the process gas into a process chamber and a block part. The component may have a first mating portion, and the block part may have a second mating portion adapted to correspond to the first mating portion, so as to align and secure the component to the block part.

The first mating portion may engage with the second mating portion to securely connect the component and the block part.

The first mating portion may be a plurality of fastening parts, and the second mating portion may be a plurality of fastening grooves corresponding to the plurality of fastening parts.

The fastening grooves may be formed at an upper region of the block part, and the fastening parts may be formed on a lower region of the component. The fastening parts may be formed on opposite side ends of the component.

The fastening grooves and the fastening parts may form an alignment key. The alignment key may be shaped in a generally triangular shape.

The component may include a first process gas supply line in which the process gas may be supplied into the process chamber, and the block part may include a second process gas supply line connected to the first process gas supply line. The first process gas supply line may be between two adjacent first mating portions. The second process gas supply line may surround two adjacent second mating portions.

The first mating portion may be a plurality of fastening grooves, and the second mating portion may be a plurality of fastening parts corresponding to the plurality of fastening grooves.

The gas box module may further include a seal adapted to seal the first process gas supply line of the component and the second process gas supply line of the block part.

The fastening parts may be formed at an upper region of the block part, and the fastening grooves may be formed within a lower region of the component.

The first mating portion may be a combination of fastening parts and fastening grooves. The second mating portion may be a combination of fastening parts and fastening grooves corresponding to the respective combination of fastening parts and fastening grooves of the first mating portion.

The combination of fastening parts and fastening grooves may be formed at an upper region of the block part, and the combination of fastening parts and fastening grooves may be formed on a lower region of the component.

The component may be at least one of a gas line, a regulator, a manual valve, an air valve, and a mass flow controller (MFC).

The component may include a first process gas supply line in which the process gas may be supplied into the process chamber. The block part may include a second process gas supply line connected to the first process gas supply line, and a seal may be adapted to seal the first process gas supply line of the component and the second process gas supply line of the block part. The fastening parts formed on the components and the fastening grooves formed in the block part may form an alignment key for aligning the component and to the block part.

### BRIEF DESCRIPTION OF THE DRAWINGS

The above and other features and advantages of example embodiments will become more apparent to those of ordinary skill in the art by describing in detail example embodiments thereof with reference to the attached drawings, in which:

FIG. 1 illustrates a plan view of a conventional block type gas box module for a semiconductor device manufacturing equipment;

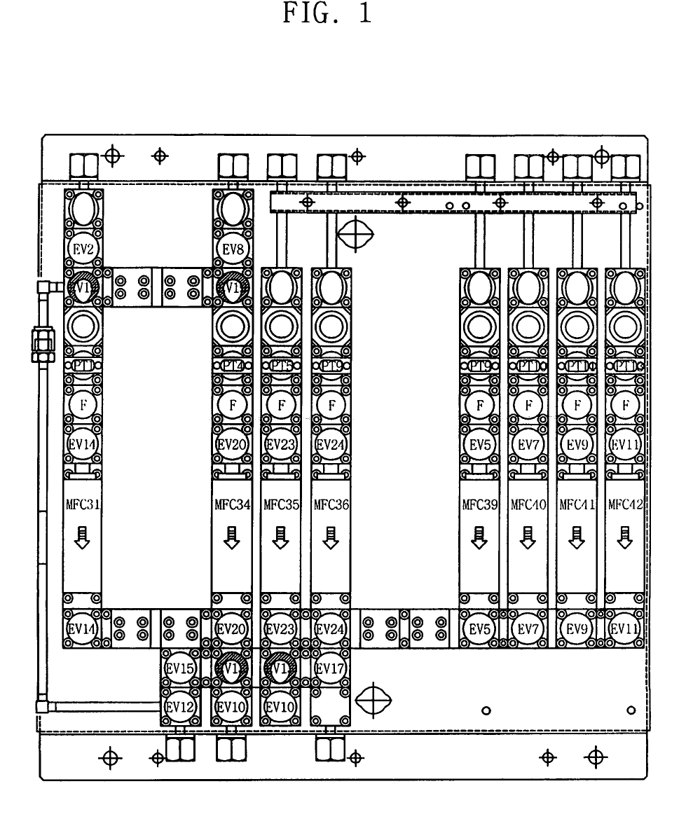

FIG. 2 illustrates a view of a portion of the gas box module shown in FIG. 1;

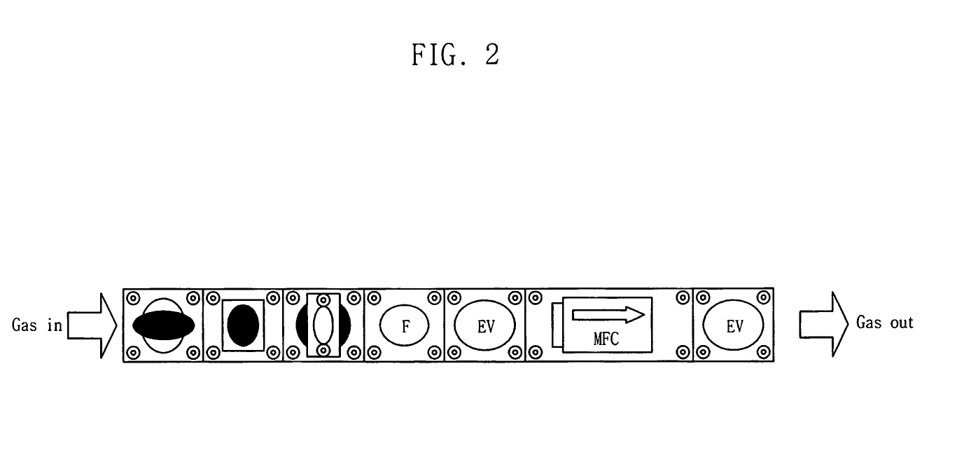

FIG. 3 illustrates a view of a gas box module in accordance with an example embodiment, before the gas box module is assembled;

FIG. 4 illustrates a view of the gas box module shown in FIG. 3, after the gas box module is assembled;

FIG. 5 illustrates a view of a gas box module in accordance with another example embodiment, before the gas box module is assembled;

FIG. 6 illustrates a view of the gas box module shown in FIG. 5, after the gas box module is assembled;

FIG. 7 illustrates a view of a gas box module in accordance with a further example embodiment, before the gas box module is assembled;

FIG. 8 illustrates a view of the gas box module shown in FIG. 7, after the gas box module is assembled;

FIG. 9 illustrates a view of a gas box module in accordance with a still further example embodiment, before the gas box module is assembled; and

FIG. 10 illustrates a view of the gas box module shown in FIG. 9, after the gas box module is assembled.

### DETAILED DESCRIPTION OF THE INVENTION

Korean Patent Application No. 10-2006-0130574, filed on Dec. 20, 2006, in the Korean Intellectual Property Office, and entitled: “Gas Box Module of Semiconductor Device Manufacturing Equipment,” is incorporated by reference herein in its entirety.

In a conventional gas box module for supplying a process gas into a process chamber, in which a unit process for manufacturing a semiconductor device may be performed, various components (e.g., a gas line, a regulator, a manual valve, an air valve, a mass flow controller (MFC), etc.) of the gas box module may be connected to a block part using a conventional screw. However, when the conventional screw is used during an attachment or detachment of the components to the block part (in order to repair and/or maintain the gas box module), the components may be misaligned, which may wear the screw, and thus, any seal (e.g., a gasket) employed in the gas box module may be damaged. As a result, the process gas may leak due to the shifting of the components, which may make it difficult to smoothly supply the process gas into the process chamber.

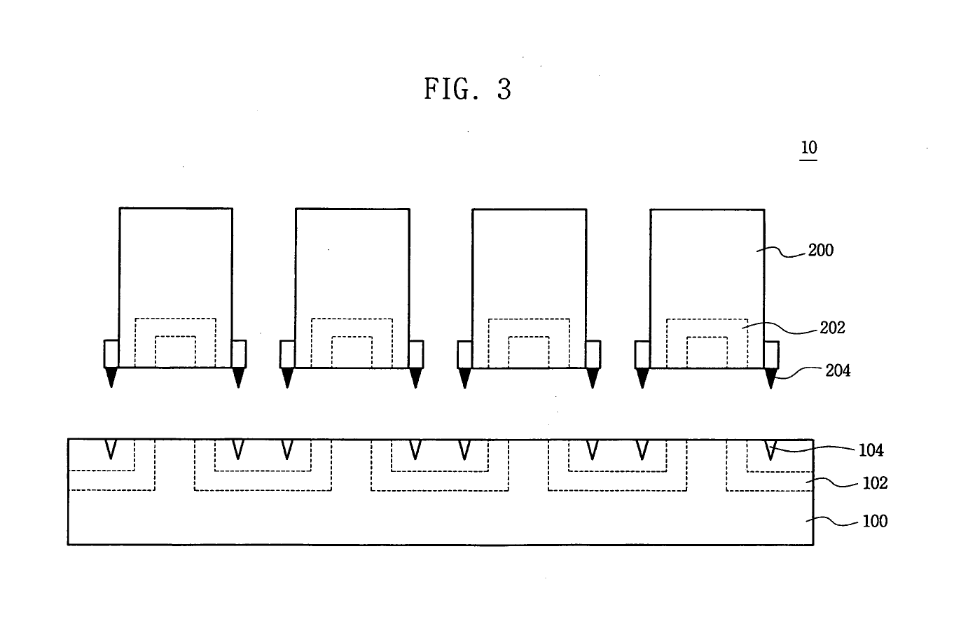

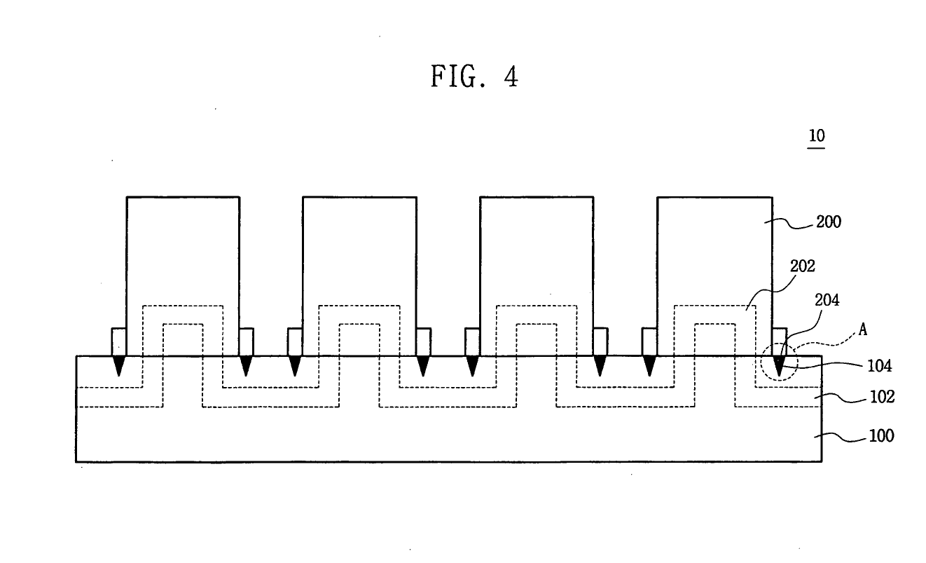

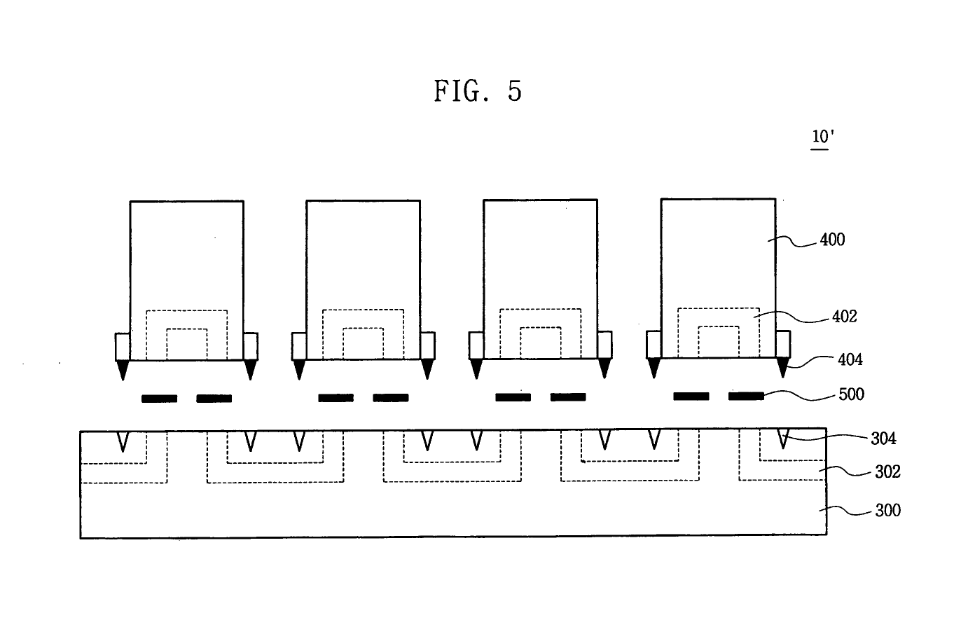

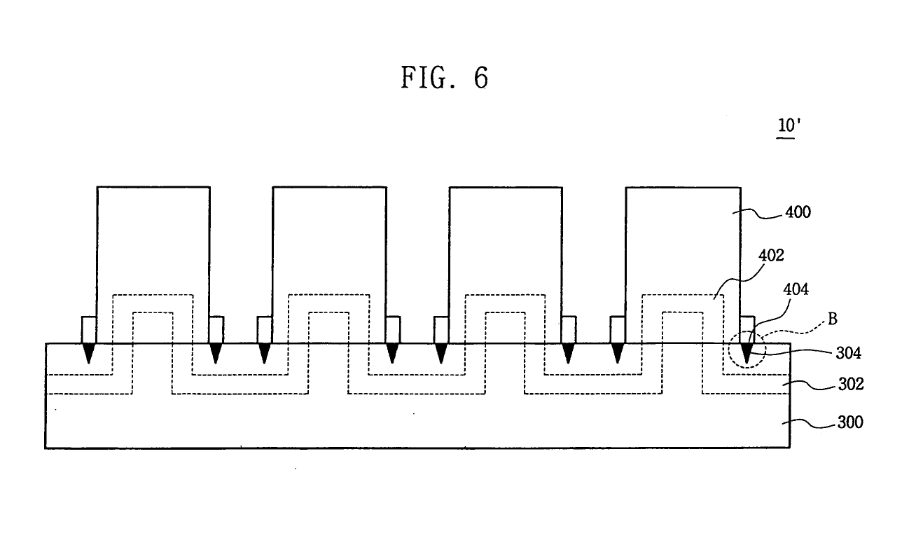

Therefore, in order to solve the above problems, fastening grooves and fastening parts adapted to fit into the fastening grooves may be employed used as an alignment key. In other words, the fastening grooves and fastening parts, which may be formed in the block part and the components, respectively, may be provided as a coupling device instead of the conventional screw. As described below in an example embodiment shown in FIGS. 3 and 4 and another example embodiment shown in FIGS. 5 and 6, fastening grooves and fastening parts, used as an alignment key, which may securely couple components with a block part, as well as precisely align the components to the block part. Further, since the conventional screw is not used, it may be possible to prevent and/or reduce damaging a seal, e.g., due to wear of the screw during a process of attaching and detaching of the components to/from the block parts.

Further, when a seal is used, a lower gas supply line and an upper gas supply line in the block part and the components, respectively, may be more closely secured to each other, so as to prevent and/or reduce gas leakage. In other words, utilizing the seal and using the fastening grooves and the fastening parts for alignment purpose, the lower gas supply line may be securely coupled and precisely aligned to the upper gas supply line.

Further, using the fastening grooves and the fastening parts as the alignment key and securely connecting the components to the block part, rather than using the conventional screw, it may be possible to prevent and/or reduce damaging the seal and shifting the components (due to wear of the conventional screw during an attachment and detachment of the components), so as to smoothly supply a process gas into a process chamber.

FIGS. 3 and 4 illustrate a gas box module 10 in accordance with in accordance with an example embodiment. FIG. 3 illustrates a view of the gas box module 10 before the gas box module 10 is assembled, and FIG. 4 illustrates a view of the gas box module 10 assembled.

Referring to FIG. 3, the gas box module 10 may include a block part 100, and a plurality of components 200 mounted on the block part 100. The components 200 may be a gas line, a regulator, a manual valve, an air valve, a mass flow controller (MFC), etc.

The block part 100 may include a lower gas supply line 102 and fastening grooves 104 (e.g., an alignment key). Each of the plurality of components 200 may include an upper gas supply line 202 and fastening parts 204 (e.g., an alignment key).

In the block part 100, the lower gas supply line 102 may be formed within the block part 100, and the fastening grooves 104 may be formed in the block part 100. The fastening grooves 104 may be spaced apart from the lower gas supply line 104 by a gap.

In each component 200, the upper gas supply line 202 may be formed within the component 200, which may correspondingly be connected to the lower gas supply line 102 formed in the block part 100, and the fastening parts 204 may project from the component 200, which may be coupled to the fastening grooves 104 formed in the block part 100.

More specifically, the fastening grooves 104 may be formed at an upper region of the block part 100, and the fastening parts 204 may be formed at both sides of a lower region of the component 200, so as to be connected to the fastening grooves 104 formed in the block part 100.

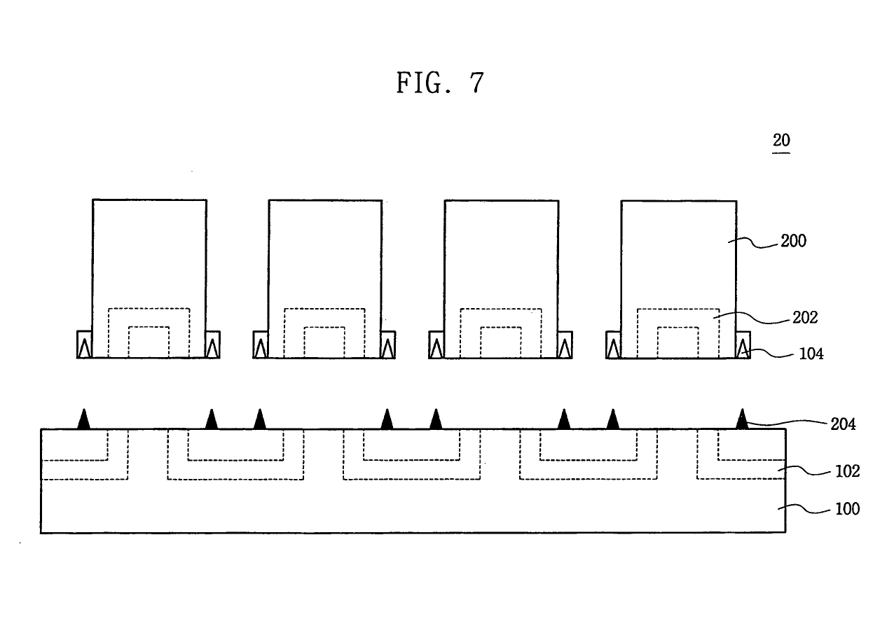

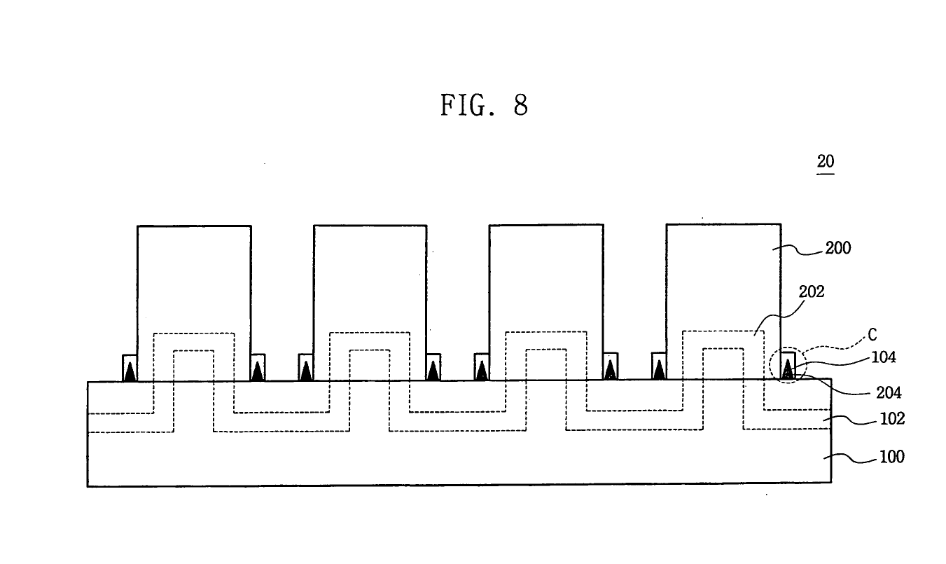

It should be appreciated that there may be only a single fastening groove 104 and a corresponding single fastening part 204. Alternatively, there may be a plurality of fastening grooves 104 and a corresponding plurality of fastening parts 204 coupled with the fastening grooves 104. It should be appreciated that the number of fastening grooves 104 and fastening parts 204 may be dependent on various conditions, such as, but not limited to, area, size, mass and weight of the components 200. Further, while the fastening grooves 104 herein been illustrated as being on the block part 100, and the fastening parts 204 have been illustrated as being on the components 200, this arrangement may be reversed as shown in FIGS. 7 and 8. Further, both types of interlocking mechanisms may be on both of the block 100 and the components 200.

FIG. 4 illustrates a view of the gas box module 10 shown in FIG. 3, having the block part 100 and the components 200 being coupled with each other by the fastening grooves 104 and the fastening parts 204 (as shown by reference character A).

Referring to FIG. 4, the fastening parts 204 formed at both sides of the lower region of the component 200 may be fastened to the fastening grooves 104 formed at the upper region of the block part 100, so as to form the gas box module 10. The fastening parts 204 and the fastening grooves 104 may be employed to securely connect the plurality of components 200 constituting the gas box module 10 to the block part 100 as well as mount the components 200 on a precise position of the block part 100 without using a separate alignment apparatus. Accordingly, when the components 200 are precisely aligned to the block part 100, the lower gas supply line 102 formed in the block part 100 may be precisely aligned to the upper gas supply line 202 formed in the component 200, such that a process gas can be efficiently supplied into a process chamber (not shown). In other words, the fastening parts 204 and the fastening grooves 104 may be employed as a precision tool to accurately align the block part 100 and the components 200.

FIGS. 5 and 6 illustrate a gas box module 10′ in accordance with another example embodiment. FIG. 5 illustrates a view of the gas box module 10′ before the gas box module 10′ is assembled, and FIG. 6 illustrates a view of the gas box module 10′ assembled.

Referring to FIG. 5, the gas box module 10′ may include a block part 300, a plurality of components 400 mounted on the block part 300, and a seal 500 for securely sealing the components 400 to the block part 300.

The block part 300 may include a lower gas supply line 302 and fastening grooves 304. The components 400 may include an upper gas supply line 402 and a plurality of fastening parts 404.

In the block part 300, the lower gas supply line 302 may be formed, and the fastening grooves 304 may be formed in the block part 300, and spaced apart from the lower gas supply line 302 by a gap.

In each components 400, the upper gas supply line 402 may be formed within the component 400, which may correspondingly be connected to the lower gas supply line 302 formed in the block part 300, and the fastening parts 404 may be formed on the component 400 to be correspondingly coupled to the fastening grooves 304 formed in the block part 300.

More specifically, the fastening grooves 304 may be formed at an upper region of the block part 300, and the fastening parts 404 may be formed at both sides of a lower region of the component 400, so as to correspond to the fastening grooves 304 formed in the block part 300.

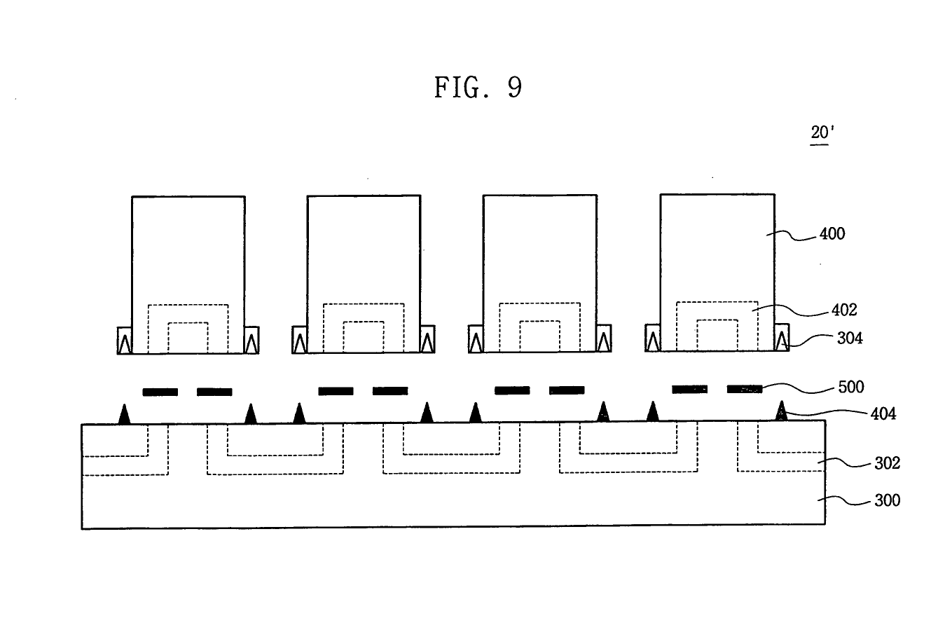

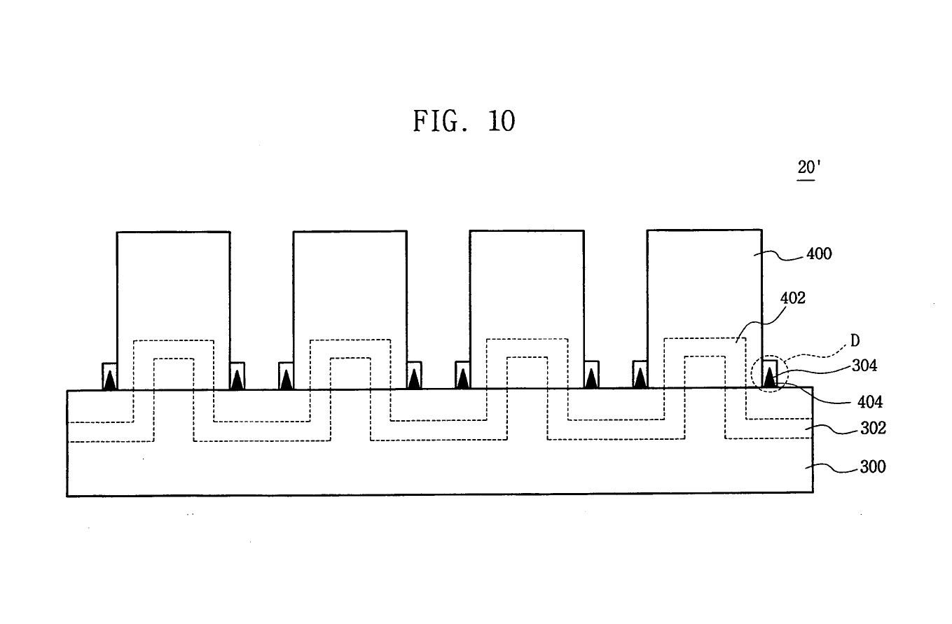

It should be appreciated that there may only be a single fastening groove 304 and a corresponding single fastening part 404. Alternatively, there may be a plurality of fastening grooves 304 and a plurality of corresponding fastening parts 404 coupled with the fastening grooves 304. It should be appreciated that the number of fastening grooves and fastening part may be dependent on various conditions, such as, but not limited to, area, size, mass and weight of the components. Further, while the fastening grooves 304 herein been illustrated as being on the block part 300, and the fastening parts 404 have been illustrated as being on the components 400, this arrangement may be reversed as shown in FIGS. 9 and 10. Further, both types of interlocking mechanisms may be on both of the block 300 and the components 400.

Further, the seal 500 (e.g., a gasket) may be interposed between the block part 300 and the component 400 to securely attach the lower gas supply line 302 formed in the block part 300 and the upper gas supply line 402 formed in the component 400.

It should be appreciated that the seal 500 may formed of a rubber, a metal, a paper, a silicon, a cork, a felt, a fiberglass, a plastic polymer, or other materials, as long as the seal prevents and/or reduces leakage of fluid. It should further be appreciated that adhesives may be adhered to the seal 500.

It should also further be appreciated that there may be more than one seal 500 interposed between the block part 300 and the component 400.

FIG. 6 illustrates a view of the gas box module 10′ shown in FIG. 5, having the block part 300 and the components 400 being coupled with each other by the fastening grooves 304 and the fastening parts 404 (as shown by reference character B).

Referring to FIG. 6, the fastening parts 404 formed at both sides of the lower region of the component 400 may be fastened to the fastening grooves 304 formed at the upper region of the block part 300 to form the gas box module 10′. The fastening parts 404 and the fastening grooves 304 may be employed to securely couple the plurality of components 400 constituting the gas box module 10′ to the block part 300 as well as mount the component 400 on a precise position of the block part 300 without using a separate alignment apparatus. Accordingly, when the components 400 are precisely aligned to the block part 300, the lower gas supply line 302 formed in the block part 300 may be precisely aligned to the upper gas supply line 402 formed in the component 400, such that a process gas can be smoothly supplied into the process chamber (not shown). In other words, the fastening parts 404 and the fastening grooves 304 may be employed as a precision tool to accurately align the block part 300 and the components 400.

Although example embodiments may describe the fastening parts 104, 404 and corresponding fastening grooves 204, 304 as having a generally triangular shape, it should be appreciated that other shapes and configurations may be employed to form the fastening parts 104, 404 and corresponding fastening grooves 204, 304.

In the figures, the dimensions of regions may be exaggerated for clarity of illustration. It will also be understood that when an element is referred to as being “on” another element or substrate, it can be directly on the other element or substrate, or intervening elements may also be present. Further, it will be understood that when a element is referred to as being “under” another element, it can be directly under, and one or more intervening elements may also be present. In addition, it will also be understood that when an element is referred to as being “between” two elements, it can be the only layer between the two elements, or one or more intervening elements may also be present. Like reference numerals refer to like elements throughout.

It will be understood that, although the terms first, second, etc. may be used herein to describe various elements, these elements should not be limited by these terms. These terms are used to distinguish one element from another. For example, a first element could be termed a second element, and, similarly, a second element could be termed a first element, without departing from the scope of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments and is not intended to be limiting of the invention. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Example embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A gas box module for supplying a process gas into a semiconductor device manufacturing equipment, the gas box module comprising:
a component adapted to supply the process gas into a process chamber, the component including a first mating portion; and
a block part having a second mating portion adapted to correspond to the first mating portion, so as to align and secure the component to the block part.

2. The gas box module as claimed in claim 1, wherein the first mating portion engages with the second mating portion to securely connect the component and the block part.

3. The gas box module as claimed in claim 1, wherein the first mating portion is a plurality of fastening parts.

4. The gas box module as claimed in claim 3, wherein the second mating portion is a plurality of fastening grooves corresponding to the plurality of fastening parts.

5. The gas box module as claimed in claim 4, wherein the fastening grooves are formed at an upper region of the block part, and the fastening parts are formed on a lower region of the component.

6. The gas box module as claimed in claim 5, wherein the fastening parts are formed on opposite side ends of the component.

7. The gas box module as claimed in claim 1, wherein the first mating portion and the second mating portion form an alignment key.

8. The gas box module as claimed in claim 7, wherein the alignment key is shaped in a generally triangular shape.

9. The gas box module as claimed in claim 1, wherein the component includes a first process gas supply line in which the process gas is supplied into the process chamber, and the block part includes a second process gas supply line connected to the first process gas supply line.

10. The gas box module as claimed in claim 9, wherein the first process gas supply line is between two adjacent first mating portions.

11. The gas box module as claimed in claim 10, wherein the second process gas supply line surrounds two adjacent second mating portions.

12. The gas box module as claimed in claim 9, further comprising a seal adapted to seal the first process gas supply line of the component and the second process gas supply line of the block part.

13. The gas box module as claimed in claim 1, wherein the first mating portion is a plurality of fastening grooves.

14. The gas box module as claimed in claim 13, wherein the second mating portion is a plurality of fastening parts corresponding to the plurality of fastening grooves.

15. The gas box module as claimed in claim 14, wherein the fastening parts are formed at an upper region of the block part, and the fastening grooves are formed within a lower region of the component.

16. The gas box module as claimed in claim 1, wherein the first mating portion is a combination of fastening parts and fastening grooves.

17. The gas box module as claimed in claim 16, wherein the second mating portion is a combination of fastening parts and fastening grooves corresponding to the respective combination of fastening parts and fastening grooves of the first mating portion.

18. The gas box module as claimed in claim 17, wherein the combination of fastening parts and fastening grooves is formed at an upper region of the block part, and the combination of fastening parts and fastening grooves is formed on a lower region of the component.

19. The gas box module as claimed in claim 1, wherein the component is at least one of a gas line, a regulator, a manual valve, an air valve, and a mass flow controller (MFC).

20. The gas box module as claimed in claim 1, wherein the component includes a first process gas supply line in which the process gas is supplied into the process chamber, and the block part includes a second process gas supply line connected to the first process gas supply line, the gas box module further comprising:
a seal adapted to seal the first process gas supply line of the component and the second process gas supply line of the block part,
wherein the first mating portion formed on the components and the second mating portion formed in the block part form an alignment key for aligning the component to the block part.
